(19) United States
(12) Patent Application Publication
(10) Pub. No.: US 2012/0163937 A1
(43) Pub. Date: Jun. 28, 2012

(54) SOLAR PANEL RACKING SYSTEM AND TRANSPORT MECHANISM

(75) Inventor: Scott ZEMAITATIS, Cherry Hill, NJ (US)

(73) Assignee: RIGGS DISTLER & COMPANY, INC., Cherry Hill, NJ (US)

(21) Appl. No.: 13/335,034

(22) Filed: Dec. 22, 2011

Related U.S. Application Data
(60) Provisional application No. 61/427,017, filed on Dec. 23, 2010.

(51) Int. Cl. B60P 7/10; H01L 23/32

(52) U.S. Cl. 410/2; 211/41.1

(57) ABSTRACT

An apparatus for protecting solar panels during transportation to a work site is disclosed. The apparatus includes a racking system that provides ease in loading and unloading solar panels on a vehicle and protects the solar panels during transportation. The racking system may be removable from the vehicle, and be used alone or in conjunction with other racking systems to maximize the number of solar panels transported to a work site without the use of a trailer system.

### FIELD OF THE INVENTION

The disclosed embodiments relate generally to a solar panel transport system that safely and efficiently racks solar panels on an installation vehicle or other transport. More particularly, the disclosed embodiments relate to a mechanism that utilizes a rack and foam components to provide solar panel installers ease in transporting and installing solar panels on site.

### BACKGROUND OF THE INVENTION

Installation of solar panels is an increasingly common occurrence as solar energy proves to be a useful means of providing renewable energy for commercial and residential properties. Transporting the solar panels for installation, and the activity involved in mounting the solar panels can be a daunting task for the installers involved with the installation process. Solar panels can be mounted, for example, on the roof tops of buildings or houses, the ground, or on a pole. Mounting solar panels that are fragile components pose challenges and take time to install properly. The loading and unloading of the solar panels from a transportation vehicle adds additional time due to the need to be careful with fragile components of the solar panels. In addition, the transportation of the solar panels to an installation site needs to be done with care to avoid any breakage of the panels. Solar panels generally comprise glass and other fragile materials that are easily broken during handling or transporting to various sites. The challenges of quickly loading and unloading solar panels on a transportation vehicle and transporting solar panels to the installation sites are still unmet needs in the industry.

### SUMMARY AND OBJECTS OF THE INVENTION

The disclosed apparatus provides for a novel way of providing a secure and safe way to transport and load/unload solar panels from a vehicle.

One object of the invention is to provide a racking system that includes a safety foam which is disposed about the solar panels. The racking system further includes members grooved and shape as to hold the solar panels in place.

In another embodiment, the racking system may comprise a latching mechanism that allows the entire racking system to be removed from the vehicle. This feature allows ease of loading and unloading of solar panels from the vehicle. Since ease of insertion and removal of the solar panels is important to the racking system, the apparatus may also comprise of a flexible material that allows insertion and removal on the vehicle without damaging the solar panels. Examples of flexible materials include but are not limited to plastics, alloys, foams, paperboard, and any combination thereof.

In addition, a plurality of racking systems may be used and disposed on the vehicle. In one embodiment the racking system is located at various locations on the transportation vehicle. Depending on the embodiment, the racking system may be located on the sides only, the middle only or both the sides and middle of the transportation vehicle to maximize space and the amount of solar panels carried on the transportation vehicle. Additional locations of the racking system may be used on the transportation vehicle and are within the scope of this invention. The object of the present invention is to minimize damage during transportation and loading/unloading of the solar panels and maximize for the installers ease of loading/unloading the solar panels at a work site. The foregoing objects are achieved and other features and advantages of the present invention will become more apparent in light of the following detailed description of exemplary embodiments thereof, as illustrated in the accompanying drawings.

### BRIEF DESCRIPTION OF THE DRAWINGS

In the drawings, wherein similar reference characters denote similar elements throughout the several views:

FIGS. 1-17 show photographs illustrating various views of the rack system and the rack system on a transportation vehicle.

FIGS. 18-28 show details of the racking system.

### DETAILED DESCRIPTION

The invention will now be described in detail with reference to the accompanying drawings. The present invention relates to an apparatus for improving transportation and installation of solar panels. The present invention decreases the risk of breakage of the solar panels during transportation to a work site and increase the ease of use for the installers in loading/unloading the solar panels from the transportation vehicle.

The racking system allows transportation of at least 15 solar panels safely into the field for installation by a 2-man crew. Prior to the invention, much less solar panels could be transported to the field. Companies in the past have tried to ship the panels into the field using the original shipping crates, which would allow 5 solar panels to be shipped at one time, in contrast to at least 15 solar panels strategically placed in the racking system. Utilizing the racking system eliminates any need for a trailer solution and maximizes the squirt bucket storage space for increased crew efficiency.

Typically a 2 man team is needed to lift a solar panel into its own secured slot within the racking system, once the system is full of the panels, the crew must put a locking board in place and hoists for safe transportation to a job site.

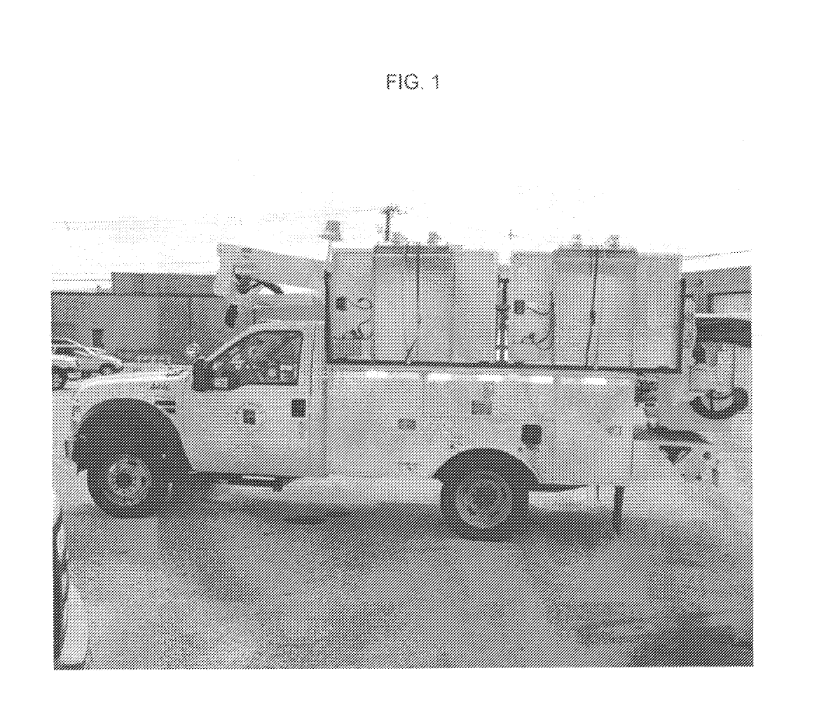

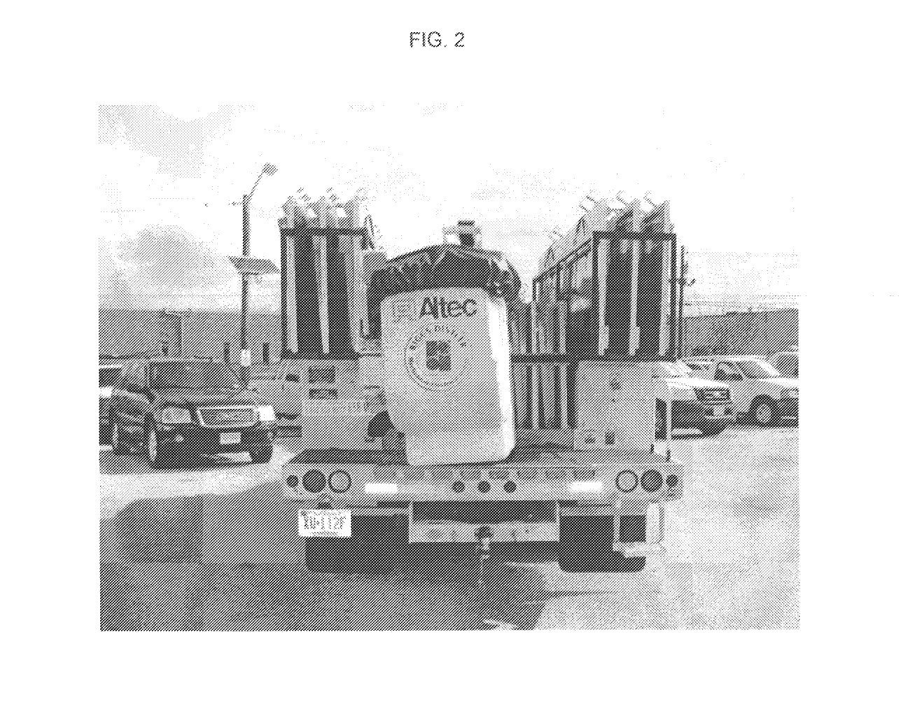

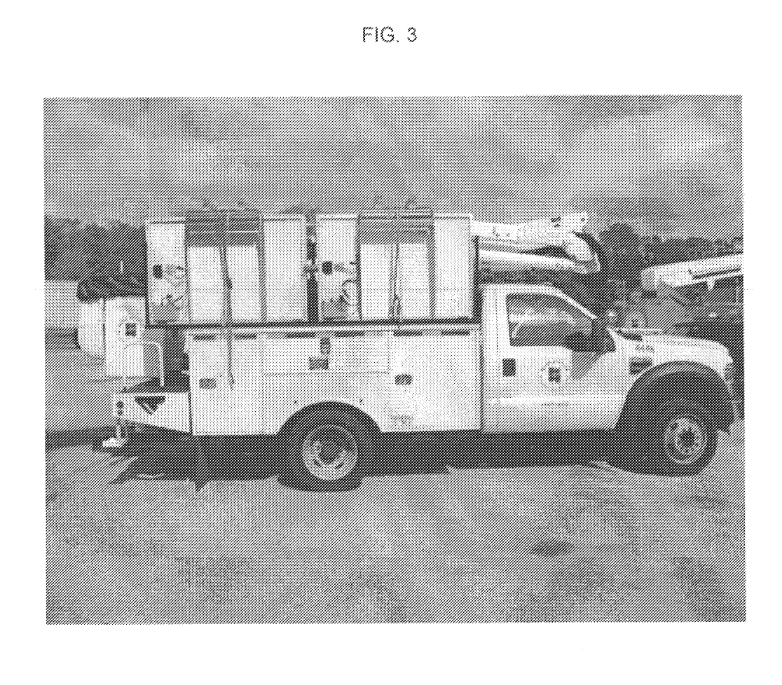

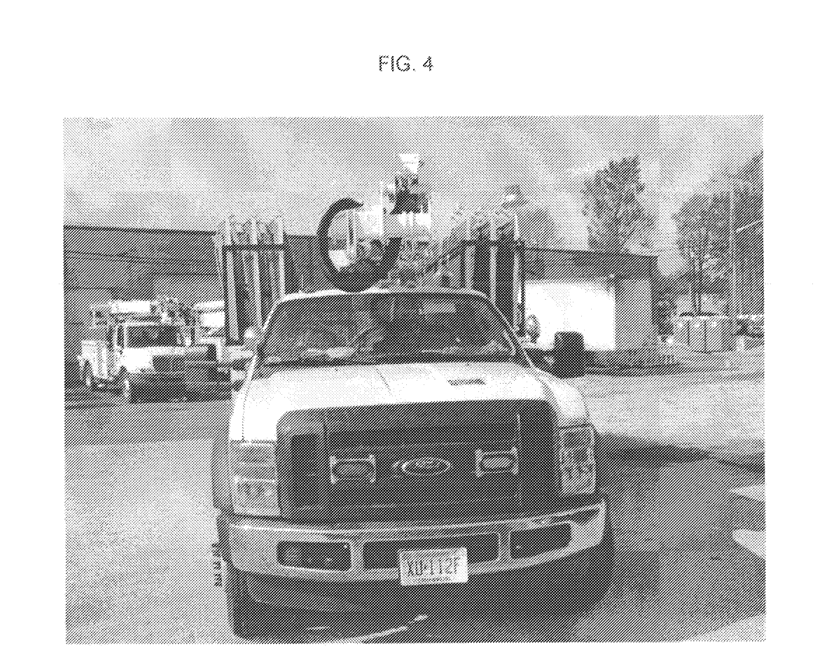

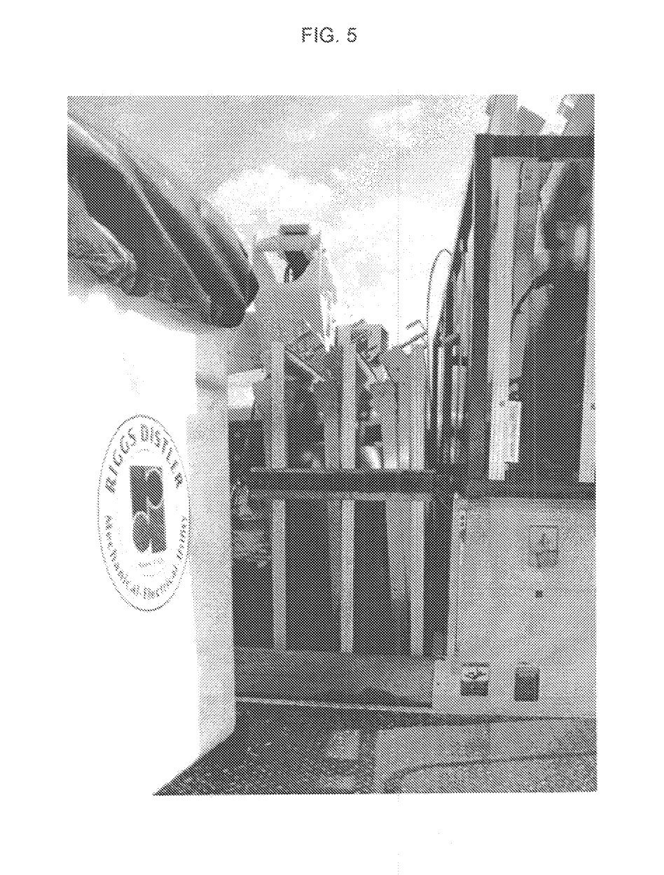

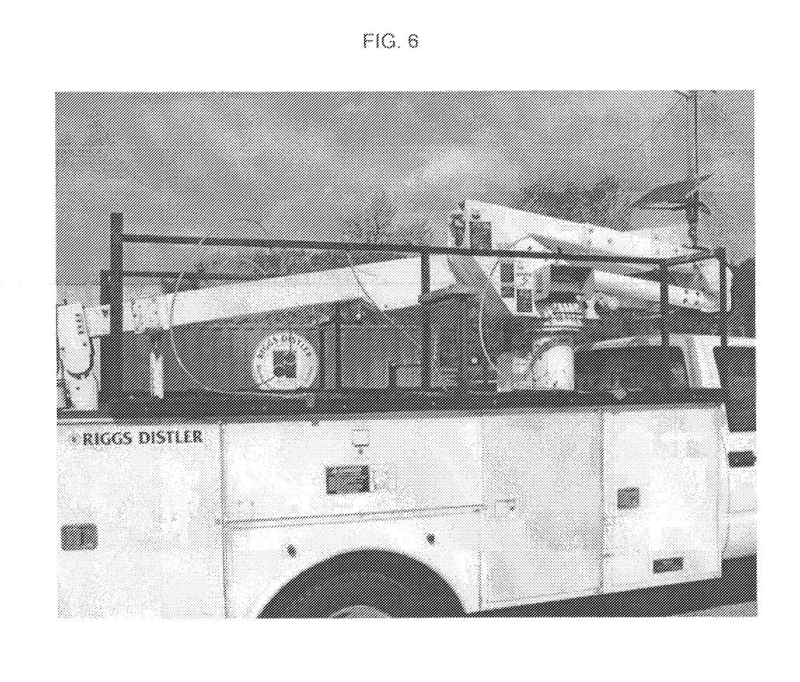

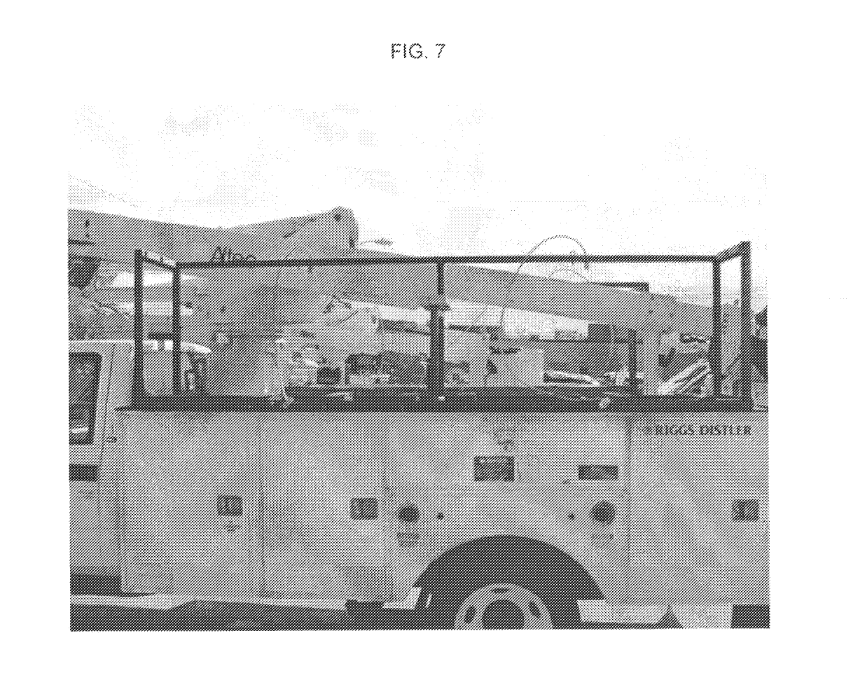

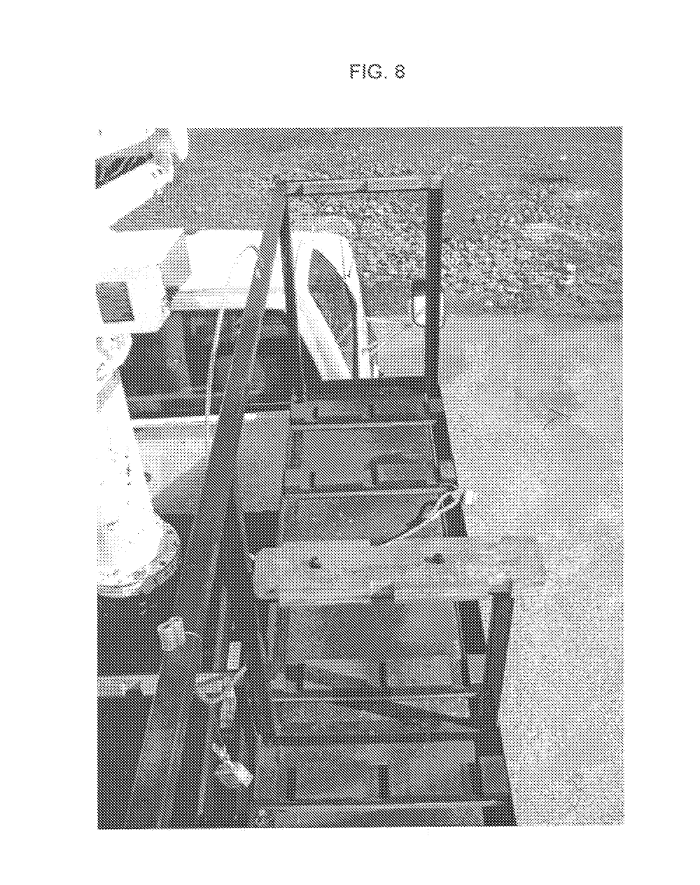

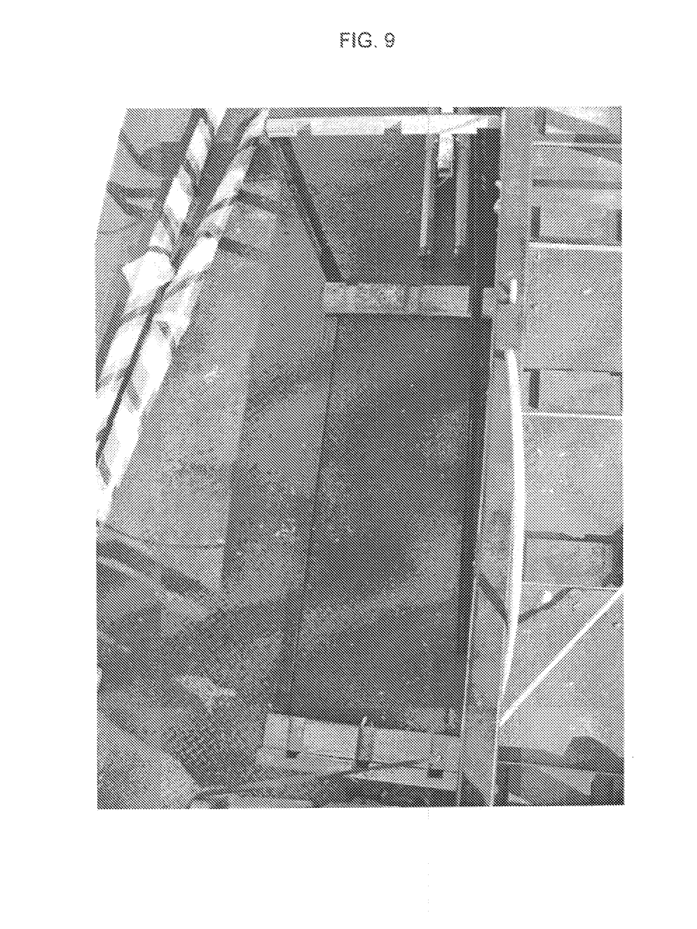

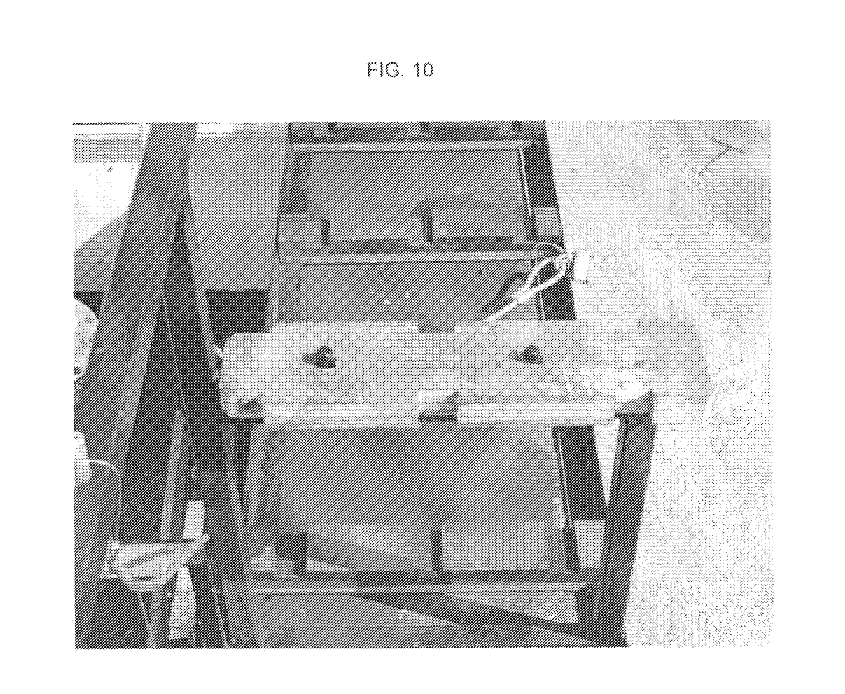

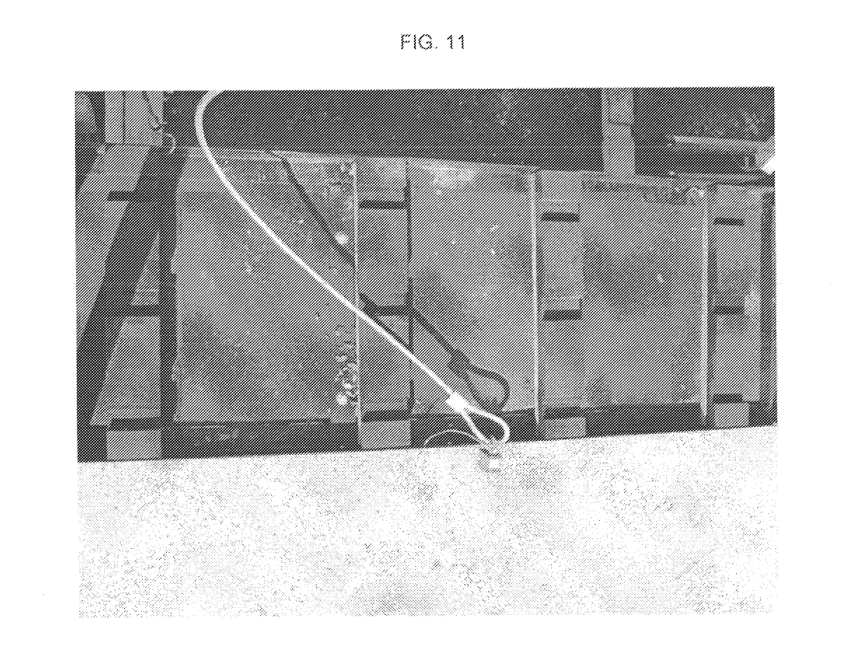

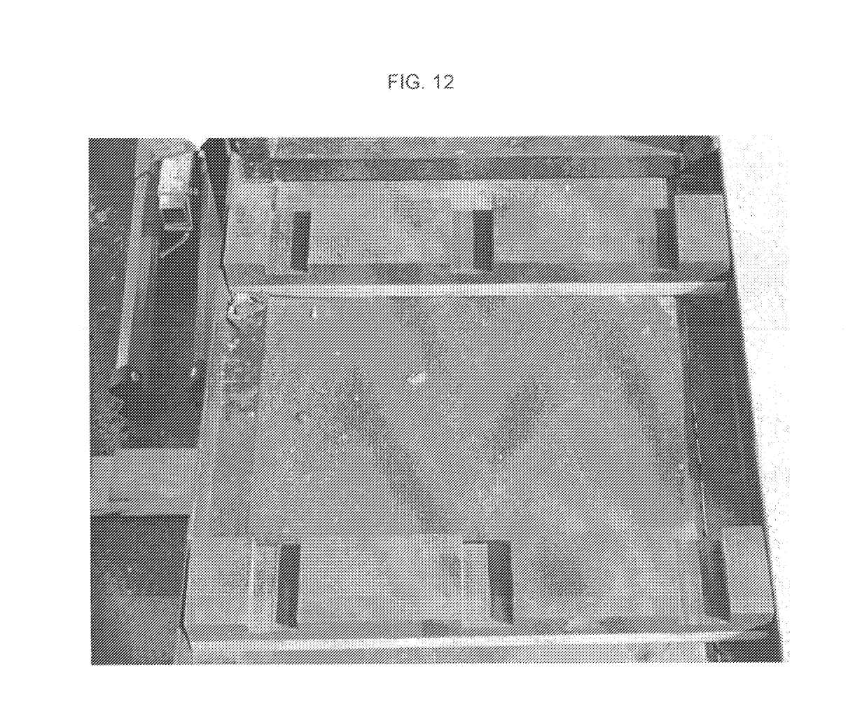

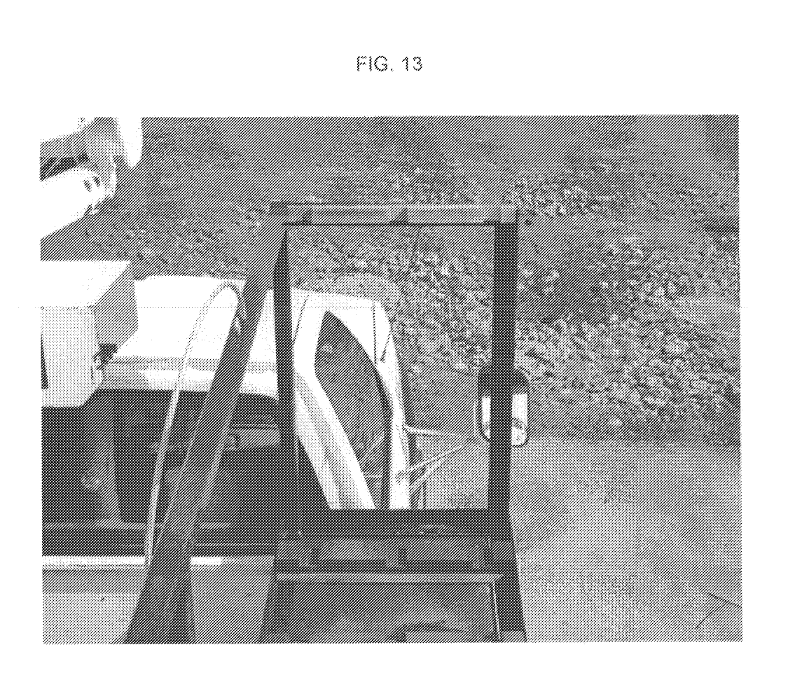

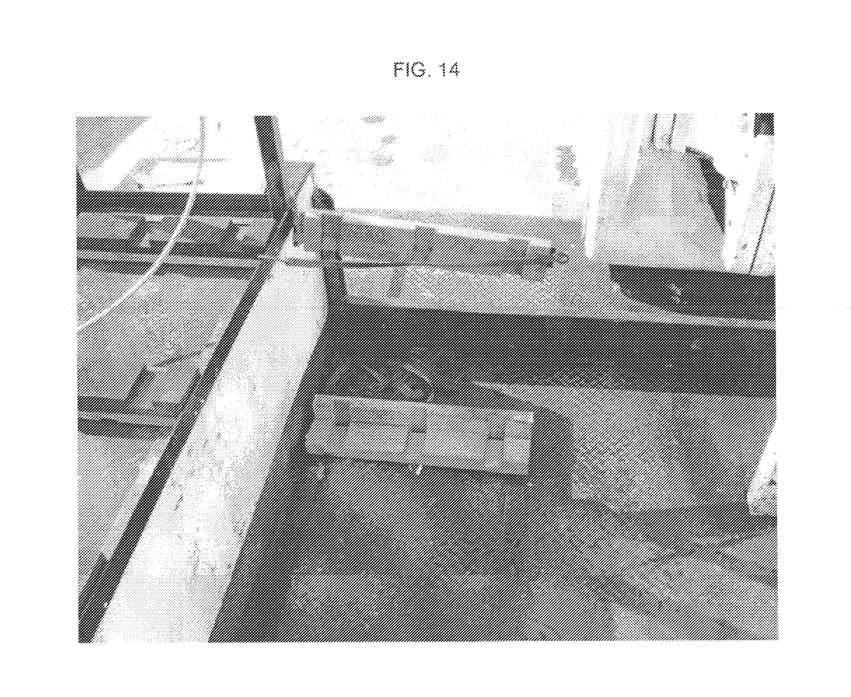

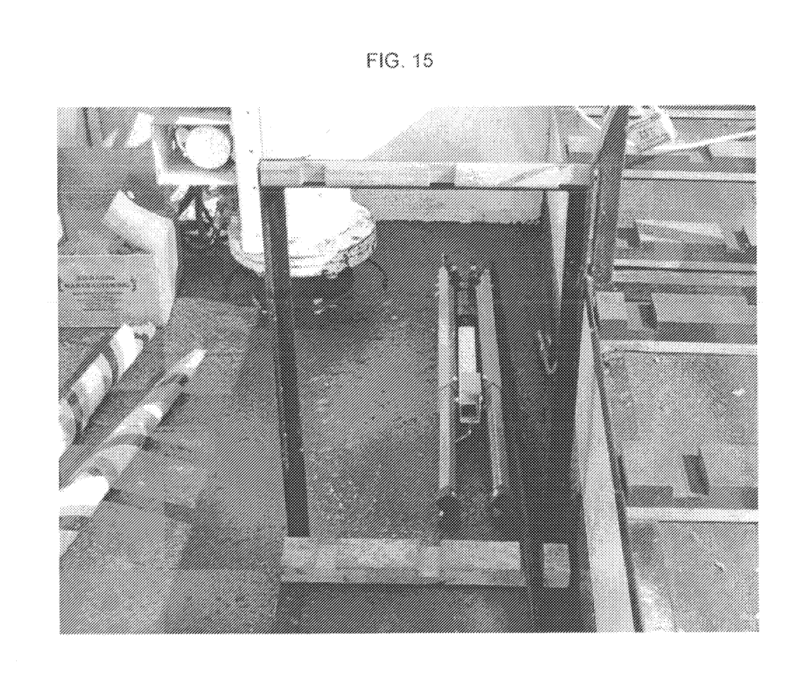

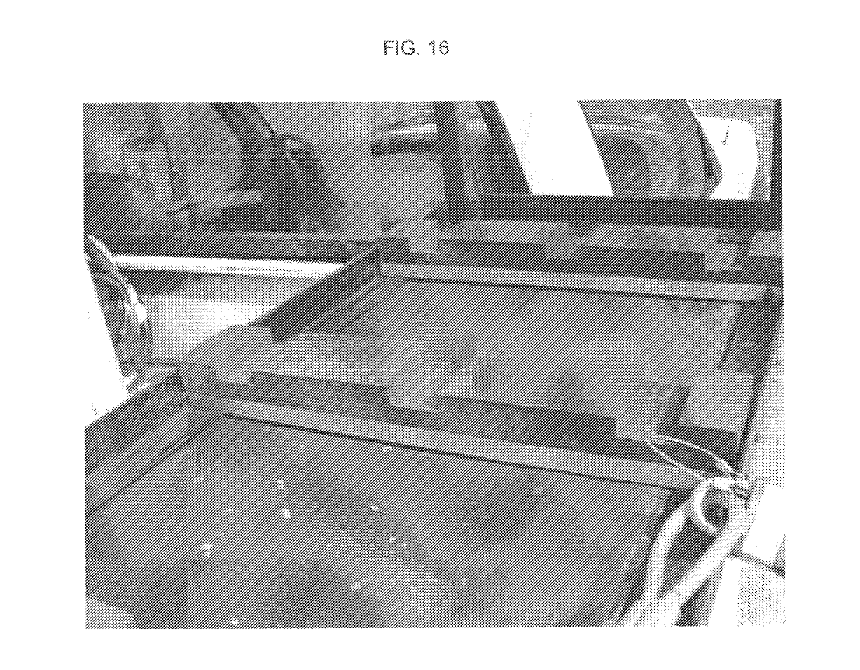

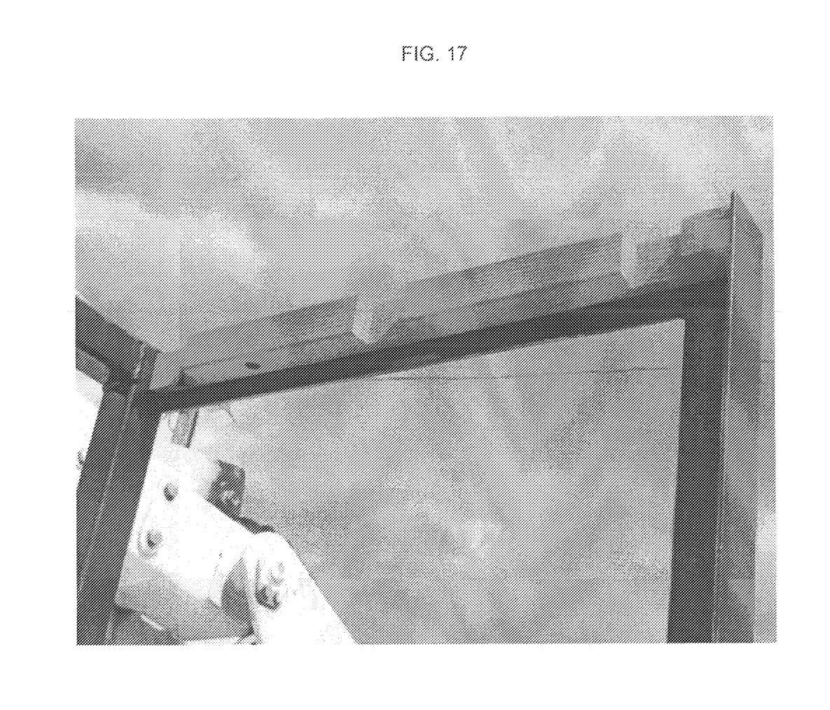

Adverting to the drawings, FIGS. 1-17 illustrate one embodiment of the invention. Shown are various views of the racking system both on and off the transportation vehicle. The racking system, depending on the embodiment, may be made removable for ease of loading/loading the solar panels.

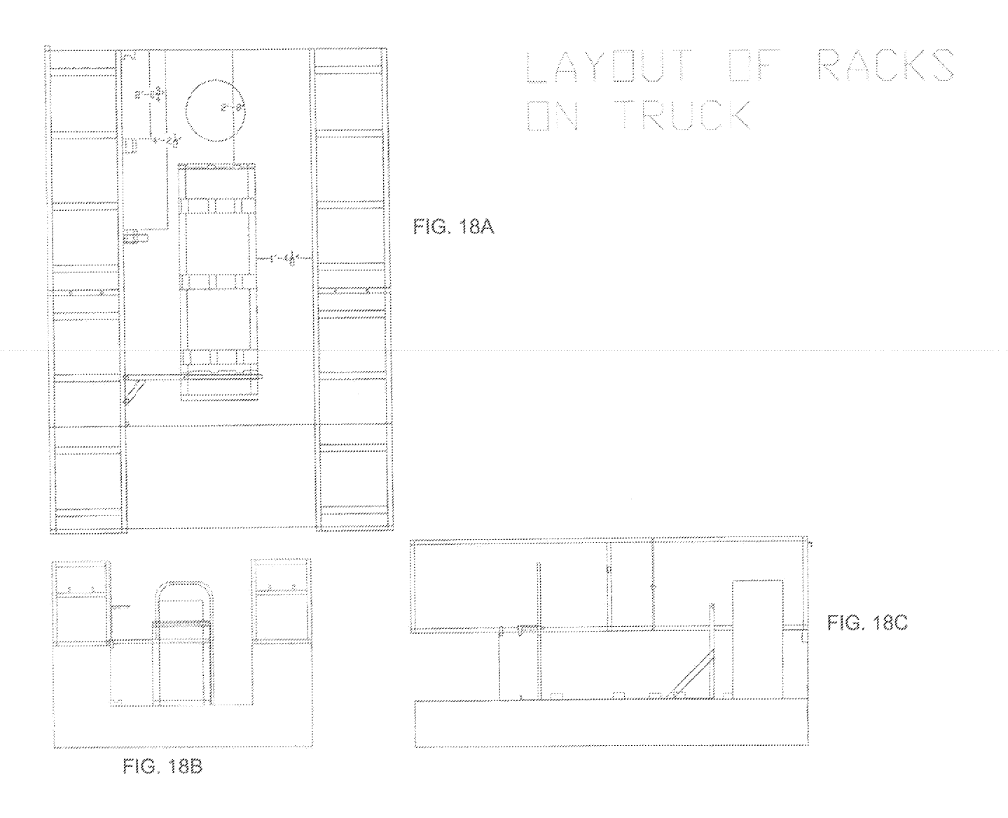

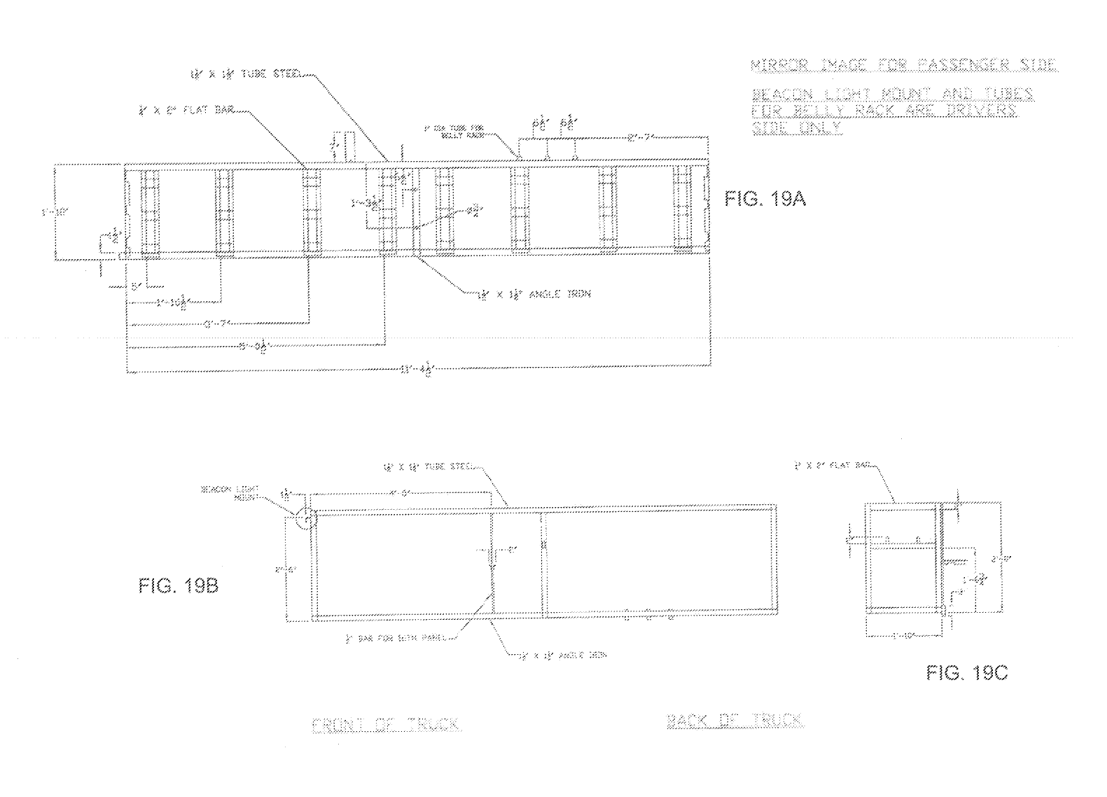

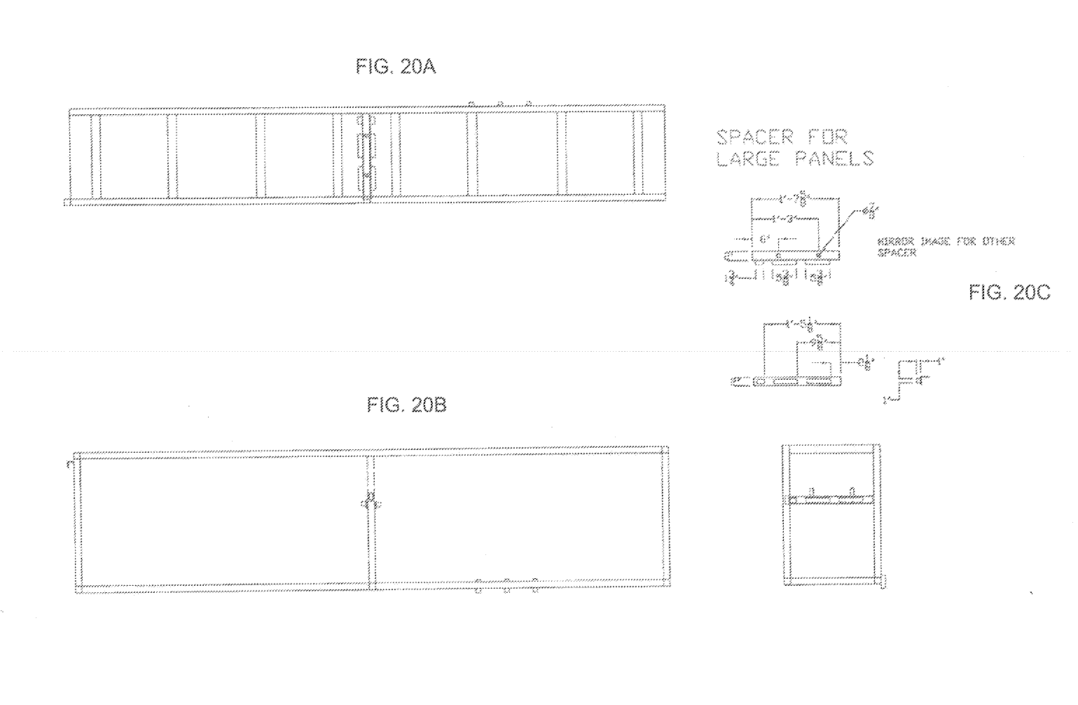

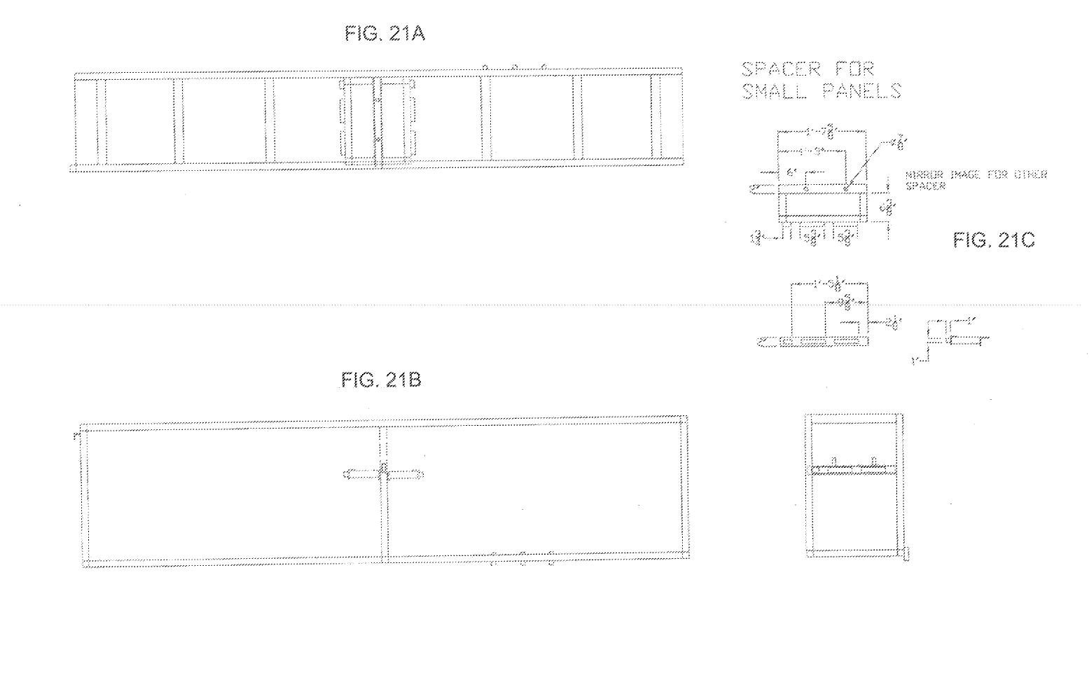

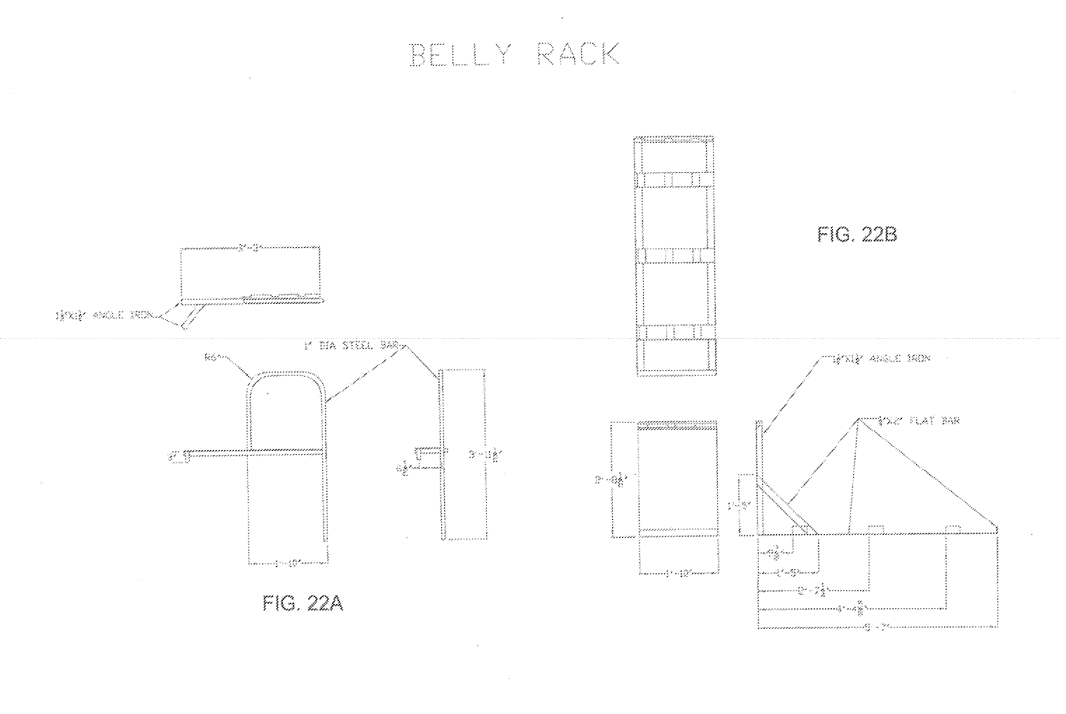

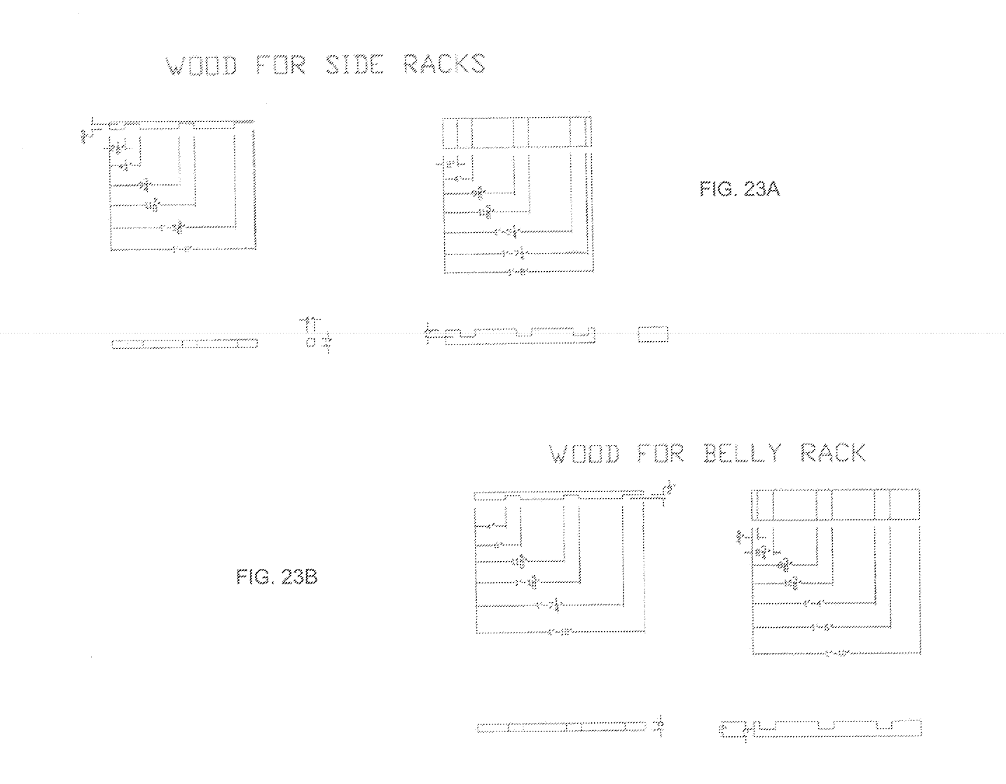

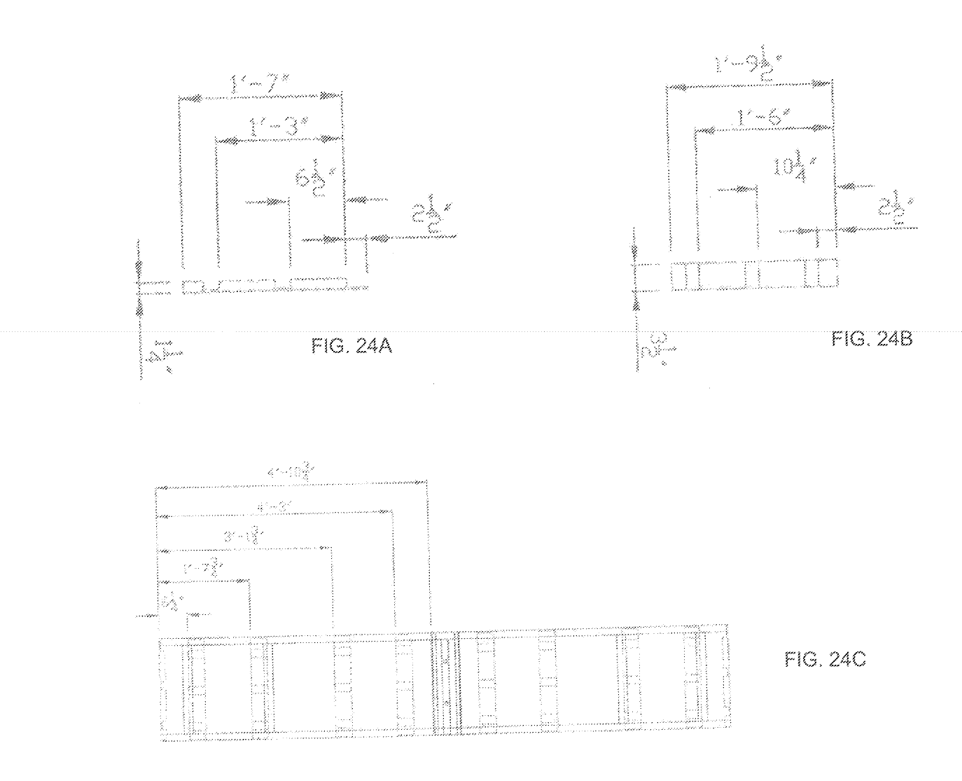

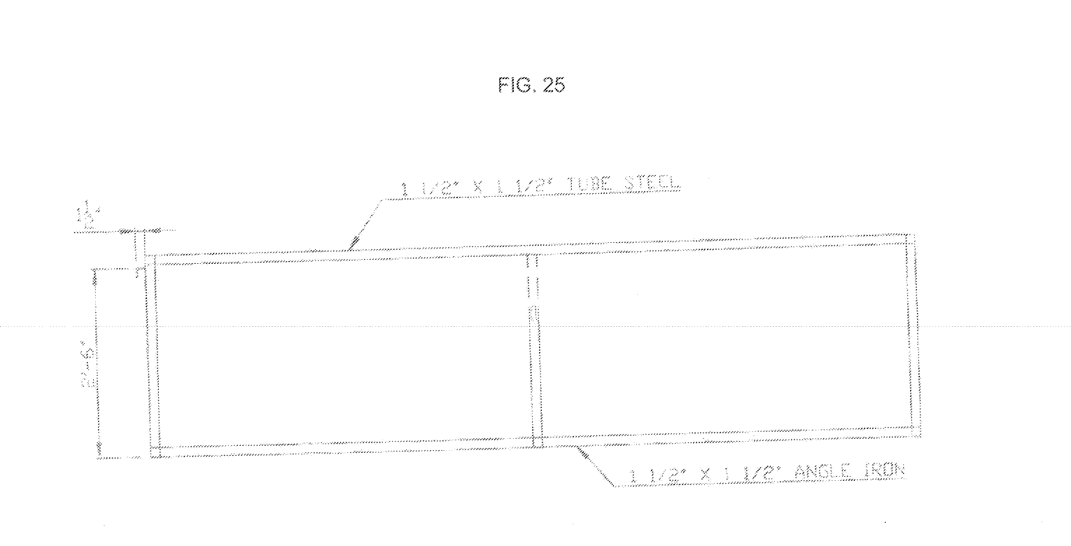

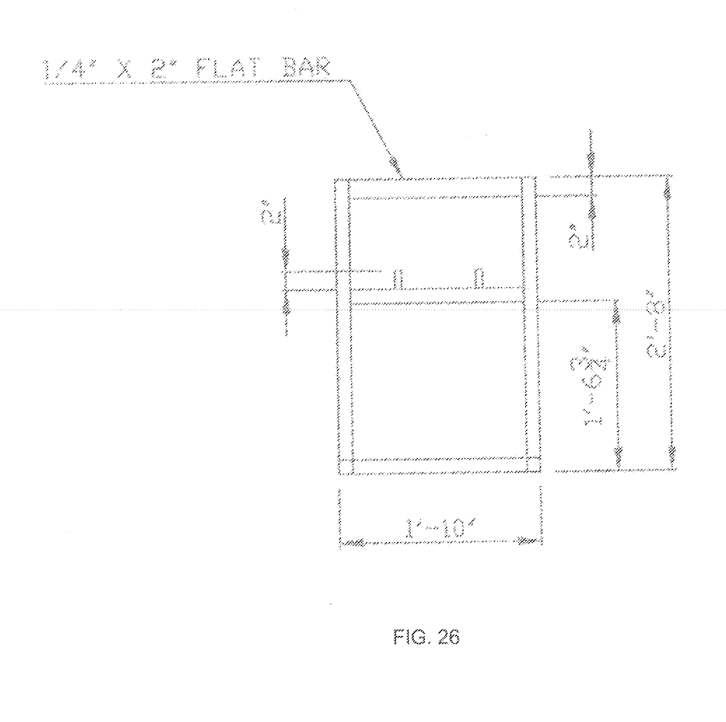

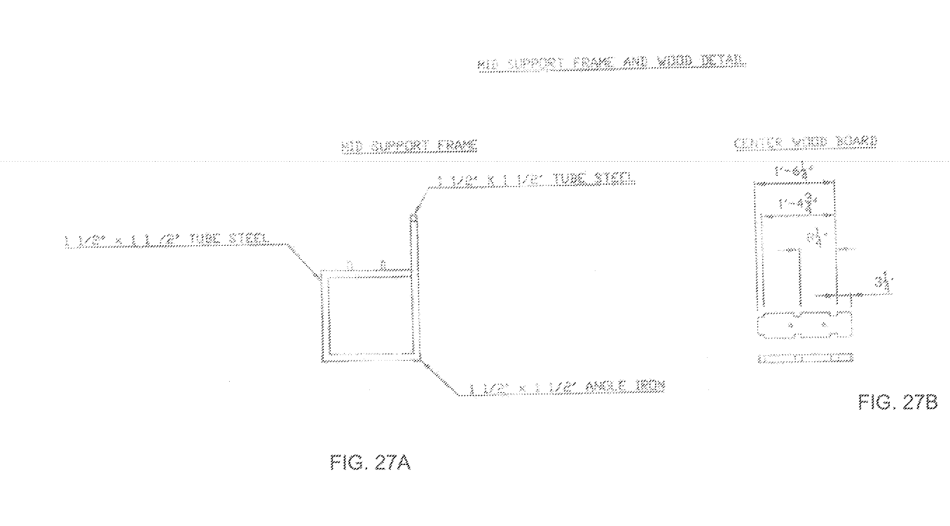

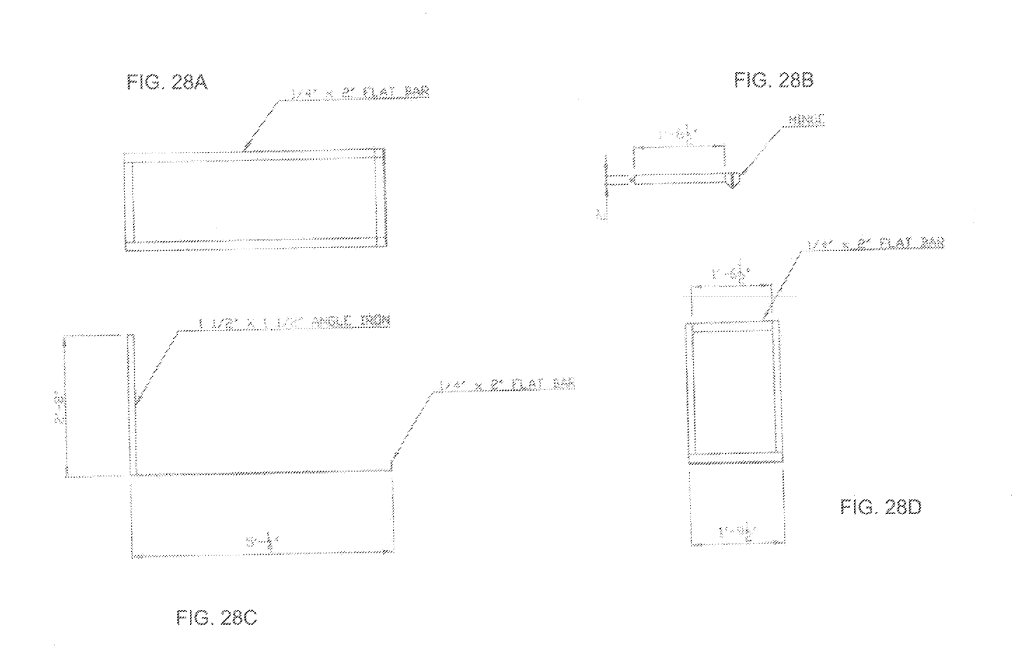

FIGS. 18-28 show details of the racking system. As shown on the mechanical drawings, the racking systems comprise of grooves to assist in the loading and unloading process of the solar panels. A mid section arm is utilized, depending on the embodiment, to assist in holding the solar panels apart from each other. An important aspect is to carefully make sure that the solar panels do not contact each other during transportation to avoid potential damage to the panels. The mid arm section and the foam assist in providing such a separation as to protect the panels from such an occurrence.

A foam is used to cushion the solar panels in the racking system. The foam provides excellent protection from shocks and vibrations. The foam may be customizable to provide a broad range of shapes and sizes. Some of the addition properties of the foam is its lightweight for loading purposes and moisture resistance for outdoor exposure.

The foam may be made of polyethylene, polypropylene, polystyrene, polyurethane or any combination thereof. Other materials of various plastics, paperboard and the like may also be used for the cushioning portion of the racking system.

Other alternative embodiments or implementations according to the various teachings of the present invention will be understood by those skilled in the art and are achieved without departing from the spirit and scope of the invention. It is therefore intended that the present invention is not limited to the disclosed embodiments described herein but should be defined in accordance with the claims that follow.

I claim:

1. An apparatus used in the transportation and installation of solar panels, comprising:
a racking system having a top and a bottom, the top defining an opening for insertion of the solar panels, the bottom defining grooves; and
a cushioning member for protecting the solar panels disposed around the solar panels on the racking system.

2. The apparatus of claim 1 further including a locking panel.

3. The apparatus of claim 1, further including a mid section arm having grooves to hold the solar panels.

4. The apparatus of claim 1 wherein the racking system is removable.

5. The apparatus of claim 1, further including a fixture for locking the racking system onto a vehicle.

6. The apparatus of claim 1, wherein the cushion is made from a material selected from the group consisting of: polyethylene, polypropylene, polystyrene, polyurethane, and any combination thereof.

7. The apparatus of claim 1, further comprising a reflective material disposed over the racking system to protect the solar panels.

8. The apparatus of claim 1, wherein multiple racking systems are connected together by connectors.

9. The apparatus of claim 1, wherein multiple racking systems are disposed on a vehicle.

10. An apparatus used in the transportation and installation of solar panels, comprising:
a racking system having a top and a bottom, the top defining an opening for insertion of the solar panels, the bottom defining grooves; and
a customize fitted foam member for protecting the solar panels disposed around the solar panels on the racking system.
